(19) United States
(12) Patent Application Publication
(10) Pub. No.: US 2024/0186996 A1
(43) Pub. Date: Jun. 6, 2024

(54) INSULATED GATE DRIVER CIRCUIT AND METHOD FOR OPERATING THE INSULATED GATE DRIVER CIRCUIT

(71) Applicant: RHEINISCH-WESTFÄLISCHE TECHNISCHE HOCHSCHULE (RWTH) AACHEN, Aachen (DE)

(72) Inventors: Lukas HÜSSEN, Aachen (DE); Muh-Dey WEI, Aachen (DE); Renato NEGRA, Aachen (DE)

(73) Assignee: RHEINISCH-WESTFÄLISCHE TECHNISCHE HOCHSCHULE (RWTH) AACHEN, Aachen (DE)

(21) Appl. No.: 18/552,157

(22) PCT Filed: Mar. 21, 2022
(86) PCT No.: PCT/EP2022/057300

§ 371 Date: Sep. 22, 2023

(30) Foreign Application Priority Data
Mar. 25, 2021 (DE) 10 2021 107 464.9

(51) Int. Cl. H03K 17/16

(52) U.S. Cl. CPC H03K 17/162; H03K 2217/0063; H03K 2217/0072; H03K 2217/0081

(57) ABSTRACT

The invention relates to an insulated gate driver circuit for driving a gate terminal of a semiconductor circuit device, including a low voltage part and a high voltage part which are galvanically separated from each other by an insulated coupling section, and the low voltage part is adapted to transmit a signal to the high voltage part comprising an output stage adapted to drive the gate terminal of the semiconductor circuit device in dependence on a switching signal underlying the signal, wherein the insulated gate driver circuit is adapted to provide a power supply to the output stage and an input signal to the output stage based on the signal transmitted via the insulated coupling section.

### CROSS-REFERENCE TO RELATED APPLICATIONS

This application is a National Stage under 35 U.S.C. 371 of International Patent Application No. PCT/EP2022/057300, filed Mar. 21, 2022, which claims priority to German Patent Application No. 102021107464.9, filed Mar. 25, 2021: the disclosures of all of which are incorporated herein by reference in their entirety.

### FIELD

The invention relates to an insulated gate driver circuit with the features of the preamble of claim 1 and a method for operating such a gate driver circuit.

### BACKGROUND

Known power electronics rely on insulated gate driver circuits for the realization of numerous applications, e.g., solar or wind power generation, power converters in electric vehicles or household appliances. The insulated gate driver circuit is a crucial component in power electronic systems for driving power electronic semiconductor circuit devices, such as gallium nitride field effect transistors in enhancement mode (eGaN FETs), silicon carbide metal-oxide-semiconductor FETs (SiC-MOS FETs), or insulated gate bipolar transistors (IGBTs). In many power electronic circuits, corresponding source terminals/emitter terminals of the semiconductor circuit devices are not connected to ground.

Instead, the source terminals/emitter terminals are connected to a floating high voltage potential that depends on the operating point of the circuit. The difference between ground and this high voltage potential can be several kilovolts. To drive such semiconductor circuit devices, the insulated gate driver circuits are used. The insulated gate driver circuits ensure proper switching operation while providing galvanic and safety insulation between the low voltage side providing the switching signal and the high voltage side connected to the high voltage potential.

However, conventional insulated gate driver circuits use transformers and optocouplers for this purpose, which are bulky and costly. In addition, the operating temperature of optocouplers is limited. Thus, power electronics are also limited in performance.

### SUMMARY

It is an object of the invention to eliminate one or more of these disadvantages.

According to the invention, this problem is solved by the features of the independent claims.

Specifically, the problem is solved by an insulated gate driver circuit for driving a gate terminal of a semiconductor circuit device. The insulated gate driver circuit comprises a low voltage part and a high voltage part. The low voltage part and the high voltage part are galvanically separated from each other by an insulated coupling section. The low voltage part is adapted to transmit a signal to the high voltage part. The high voltage part has an output stage. The output stage is adapted to drive the gate terminal of the semiconductor circuit device in dependence on a switching signal underlying the signal. The insulated gate driver circuit is further adapted to provide a power supply to the output stage and an input signal to the output stage based on the signal transmitted via the insulated coupling section. The power supply and the input signal may be provided independently of each other.

The invention has the advantage of reducing the package space of insulated gate driver circuits while saving costs. Likewise, such an insulated gate driver circuit can be operated at higher temperatures. Thus, the insulated gate driver circuit can ensure that higher power can be provided by the power electronics while maintaining the same installation space. These advantages can be achieved in particular by dispensing with bulky transformers on the one hand and costly optocouplers on the other.

The low voltage part can have a lower reference potential than the high voltage part. For example, the low voltage part may be grounded (reference potential is connected to ground) and the high voltage part may have a floating reference potential.

The insulated coupling section may be a path that establishes a distance between the high voltage part and the low voltage part. On the one hand, the insulated coupling section can provide galvanic insulation between the high voltage part and the low voltage part. On the other hand, the insulated coupling section can be used explicitly for, preferably unidirectional, communication from the low voltage part to the high voltage part. For this purpose, the low voltage part and the high voltage part may have respective communication interfaces for wireless transmission of the signal. The communication interfaces may be coils, antennas, or waveguides. The communication interfaces may face each other, separated by the insulated coupling section. Thus, the communication interfaces may be located on, preferably directly opposite, sides of the insulated coupling section.

As used herein, the term “power supply” may also be understood to mean current or voltage supply, in particular direct current or direct voltage.

Advantageous embodiments of the invention are set out in the dependent claims.

For example, the signal can be transmitted via one and the same coupling section (a channel). Exactly one communication interface for transmitting the signal may be explicitly provided at the low voltage part and the high voltage part. A side-by-side arrangement of interfaces at the low voltage part and/or the high voltage part can be omitted.

Compared to conventional insulated gate driver circuits, separate elements and thus space can be saved. Conventional insulated gate driver circuits transmit the power spatially separated from the switching signal via different coupling sections (several channels). Spatially separated transmission of signals intended for different functions can be explicitly omitted herein.

The high voltage part may have a rectifier. The rectifier may be adapted to generate and provide a DC voltage to the output stage by rectifying at least a (one) part of the signal transmitted via the insulated coupling section. In operation, the output stage may be connected directly upstream of the semiconductor circuit device. In this regard, the output stage may have two terminals. One of the terminals may be for connection to the gate terminal of the semiconductor circuit device. The other terminal may correspond to a ground of the low voltage part and may be provided for connection to a source terminal or emitter terminal of the semiconductor circuit device.

The high voltage part may have a demodulation device. The demodulation device may be arranged to generate and provide to the output stage the input signal of the output stage reflecting the switching signal by demodulating, at least, a (other) part of the signal transmitted via the insulated coupling section.

The rectifier and the demodulation device may be adapted to operate the output stage together based on one and the same signal. The power required to drive the output stage and the information required as the input signal to the output stage may be contained in the same signal transmitted via one and the same coupling section.

This can eliminate the need for a separate power supply to the high voltage part.

The coupling section can have a signal divider on the output side, preferably a Wilkinson divider or a directional coupler. The signal divider can be adapted to split the signal transmitted via the coupling section. The splitting may be done into the one and the other part of the signal transmitted over the insulated coupling section. The one and the other part may have substantially equal signal components, in particular signal powers, for example with an at least halved signal power compared to the signal transmitted over the insulated coupling section. Alternatively, the one and the other part may have different signal components, in particular signal powers. For example, a signal power of the one part may be greater than the signal power of the other part, for example greater than 10 times, or greater than 100 times, or greater than 1000 times. Thus, a larger signal power can be supplied to the rectifier than to the demodulation device. This allows the signal to be effectively used to supply power. The signal divider can be arranged, for example directly, between the insulated coupling section and the rectifier and/or the demodulation device. Thus, the coupling section can form a signal path which is separated into two signal paths by the signal divider.

This makes it easier to provide the power supply to the output stage and the input signal. This also has the advantage that the structure of the high voltage part can be simplified.

The signal can be a digitally modulated signal. Preferably, the signal can be a multiple amplitude shift keying (M-ASK) high frequency signal or a frequency shift keying (FSK) high frequency signal. Even more preferably, the signal can be a 2-ASK high frequency signal or a binary FSK (BFSK) high frequency signal.

This has the advantage that signal feedback from the high voltage part to the low voltage part is less likely to affect the operation of the insulated gate driver circuit.

The switching signal may have two states. The two states, preferably ON and OFF, for example 1 and 0 in binary form, may be represented in the 2-ASK high frequency signal by two differing amplitudes. The two states, preferably ON and OFF, for example 1 and 0 in binary form, may be mapped in the BFSK high frequency signal by two differing frequencies.

In particular, a principle of operation herein is based on differential changes in parameters of the digitally modulated signal. The differential changes contained in the digitally modulated signal may map the switching signal.

The input signal of the output stage can thus be independent of absolute values. The output signal of the output stage may be understood as a control signal for driving the gate terminal of the semiconductor circuit device.

The low voltage part may include a switching signal generator. The switching signal generator may be adapted to generate the switching signal. The switching signal may represent a desired switching state of the semiconductor circuit device. The desired switching state may correspond to an ON/OFF signal, for example, 1 and 0 in binary form.

The low voltage part may further comprise a high frequency signal generator. The high frequency signal generator may be adapted to generate a high frequency signal. The high frequency signal may have a carrier frequency of the signal.

The low voltage part may further comprise a modulation signal generator. The modulation signal generator may be adapted to generate the signal based on a combination of the high frequency signal and the switching signal. The signal, in particular the digitally modulated signal, can thus contain or combine signal components of the high frequency signal and the switching signal.

Thus, a simple circuitry can be provided at the low voltage part.

The modulation signal generator may be adapted for class E or class D operation. The rectifier may be adapted for class E operation. Further, the rectifier may be a diode rectifier, a bridge rectifier circuit, or an inverting class E rectifier. The output stage may be a linear amplifier, for example of class AB. The demodulation device may be a differential amplifier or may be adapted as such.

This can save power dissipation.

The above problem is also solved by a method for operating an insulated gate driver circuit. Preferably, this is the insulated gate driver circuit described above. The method comprises providing a low voltage part and a high voltage part. The low voltage part is galvanically separated from the high voltage part by an insulated coupling section. The method further comprises wirelessly transmitting a signal, from the low voltage part to the high voltage part via the insulated coupling section. The method further comprises driving the gate terminal of the semiconductor circuit device in dependence on a switching signal underlying the signal by an output stage of the high voltage part. The method further comprises providing a power supply to the output stage and an input signal to the output stage based on the signal transmitted via the insulated coupling section. This step of providing the power supply of the output stage and the input signal of the output stage may be performed independently at the output stage, based on one and the same signal transmitted via the insulated coupling section.

Thus, the invention has the advantage of reducing the package space of insulated gate driver circuits while saving costs.

Advances in semiconductor circuit devices have resulted in higher temperature capability of smaller form factor semiconductor circuit devices. This translates into higher performance of individual semiconductor circuit devices. However, higher switching frequencies can also be achieved with high efficiency in power electronic converters, such as bridge circuits, due to lower gate capacitances of semiconductor circuit devices.

The faster switching capability of the semiconductor circuit devices increases the voltage and current transients in the overall power electronic circuit. This poses a challenge to the insulated gate driver circuit because these transients can couple in through the parasitic coupling capacitance of the insulation between the high voltage part and the low voltage part. This can cause distortion and even failure of the low voltage part.

For this purpose, wireless coupling structures, such as coils (inductive coupling), antennas, or waveguides, can be used on opposite sides of the coupling section in the above method to transmit the signal wirelessly across the coupling section. Unlike transformer-based insulation, which inherently has a comparatively large coupling capacitance between the primary coil (low voltage part) and secondary coil (high voltage part), the coupling capacitance can be smaller for wireless coupling structures. Waveguides have the advantage that only signals above and below cutoff frequencies are transmitted, and thus spurious signals outside the bandwidth formed by the cutoff frequencies can be effectively attenuated. The carrier frequency of the signal can be fixed to be within the cutoff frequencies of the waveguides.

Wireless power transmission (WPT), for example by means of inductive coupling between the low voltage part and the high voltage part, can also save energy and space. In contrast, power transmission using transformer-based DC/DC converters or optocouplers is energy-efficient but not very space- or cost-efficient because transformers are bulky and optocouplers use optical transmission fibers as insulators, which are limited in performance and comparatively expensive, and can poorly withstand high temperatures.

High temperatures generally pose a threat to the life of transformers, optocouplers, and optical fibers. Wireless coupling structures, such as coils, antennas or waveguides, may also be less affected by this.

In particular, according to the above method, no optical and/or transformer-based power transmission or signal transmission is used. An advantage of the above method is also that the transmission of the switching signal does not require circuit elements separate from the power transmission. Power and switching signal transmission are in particular carried out in one.

In other words, the invention relates to an insulated gate driver circuit with simultaneous wireless information and power transmission. In one or more examples, an architecture is provided that uses a single wireless transmit-receive link operating in the gigahertz (GHz) frequency range with waveform shaping, and transmits both gate driver power and gate control signals simultaneously. Thus, space-, power-, and cost-efficient operation can be realized simultaneously. In addition, parasitic coupling capacitance can be kept to a minimum and high-temperature operation can be enabled.

In particular, embodiments may be directed to semiconductor power devices, automotive applications, power grids, converters, inverters, or motor controls.

In one example, a waveform modulated signal in the GHz range is generated and passed through a single high frequency coupling channel, namely the coupling section, to a rectifier, for providing a DC voltage or current, and a demodulation device, for providing a switching signal. The resulting voltage or current and the switching signal are supplied to the gate driver stage as the output stage of the gate driver circuit for switching the semiconductor circuit device connected thereto or to be connected thereto.

The waveform technique/waveform shaping used herein may be, for example, modulation of the switching signal by amplitude shift keying (ASK) or frequency shift keying (FSK).

The power of the modulated signal may be adapted to be higher than the power required by the high voltage part to operate. Further, the power of the modulated signal may be such that it is above the power required to drive the semiconductor circuit device. This may provide power for driving auxiliary circuits, for example, circuits for monitoring various parameters of the semiconductor circuit device. The power of the modulated signal may be dependent on the switching frequency of the semiconductor circuit device. Thus, the power of the modulated signal may be adapted to the switching signal or the switching frequency contained therein. The power of the modulated signal may be adjusted by adjusting the amplitude levels. Demodulation of the signal can be adapted to account for abrupt changes in amplitude or frequency for ASK or FSK, respectively, but be independent of absolute values of the signal.

Multiple ASK, multiple FSK, and orthogonal frequency division multiplexing (OFDM) may be used herein as waveform techniques to enable certain functions, such as supporting multiple semiconductor circuit devices with OFDM modulation.

Thus, another aspect may include a bridge circuit with multiple semiconductor circuit devices. Corresponding gate terminals of the semiconductor circuit devices may be connected to the gate driver circuit, as described above. Here, the digitally modulated signal may be an OFDM high frequency signal. Here, the digitally modulated signal may have multiple carriers. Here, one carrier may include the switching signal intended for the gate terminal of a corresponding semiconductor circuit device. Herein, the switching signals contained in the carriers may differ from each other. Thus, different carriers may be provided with different switching signals. Furthermore, a single, namely one and the same, coupling section may be used.

The principle of waveform shaping offers many possibilities and advantages compared to other approaches of conventional technology and supports high efficiency or high robustness depending on the requirements. One or more high frequency filters may further be arranged in the insulated gate driver circuit to suppress noise and/or electromagnetic interference (EMI) to increase robustness. For example, a first high frequency filter may be arranged directly before the demodulation device, for example between the signal divider and the demodulation device. A second high frequency filter may be arranged, for example, directly downstream of the modulation signal generator, for example, between the modulation signal generator and the interface between the low voltage part and the coupling section.

In one or more examples, the insulated gate driver circuit may be implemented in a more space efficient manner than the prior art due to the single high frequency coupling channel. The high frequency coupling channel at GHz frequencies has the unique advantage of minimal coupling capacitance between the low and high voltage sides, thereby reducing transient coupling. The insulated gate driver circuit described herein can be operated at high temperatures since all components can be implemented with high temperature components. Further, the insulated gate driver circuit may be fully integrated with the semiconductor circuit device on the same die, i.e., a semiconductor chip.

In summary, one or more of the following advantages can be achieved by the insulated gate driver circuit disclosed herein: ultra-compact size, fast switching speed and low pulse width modulation (PWM) duty cycles, robustness, high-temperature operation, and lower cost since no optical fibers are used.

It is understood by those skilled in the art that the explanations set forth herein may be/are implemented using hardware circuitry, software means, or a combination thereof. The software means may be related to programmed microprocessors or a general computer, an ASIC (Application Specific Integrated Circuit) and/or DSPs (Digital Signal Processors).

For example, the high voltage part and the low voltage part may be partially implemented as a computer, a logic circuit, a field programmable gate array (FPGA), a processor (for example comprising a microprocessor, a microcontroller (μC) or a vector processor), a core (may be integrated in the processor or used by the processor) and/or a central processing unit (CPU).

In further examples, the high voltage part and the low voltage part may be partially implemented as an FPU (Floating Point Unit), an NPU (Numeric Processing Unit), and/or an ALU (Arithmetic Logical Unit).

In a still further exemplary embodiment, the high voltage part and the low voltage part may be partially implemented as a coprocessor (additional microprocessor to support a main processor (CPU)), a GPGPU (General Purpose Computation on Graphics Processing Unit), a parallel computer (for simultaneous execution, inter alia on multiple main processors and/or graphics processors, of computational operations), and/or a DSP.

However, the high voltage part and the low voltage part are not intended herein to be limited to the foregoing.

Although some of the foregoing aspects have been described with respect to the gate driver circuit, these aspects may also apply to the method of operating the gate driver circuit. Likewise, the aspects described above with respect to the method for operating the gate driver circuit may apply in a corresponding manner to the gate driver circuit.

### BRIEF DESCRIPTION OF THE DRAWINGS

The invention will be explained in more detail with reference to embodiments with reference to the accompanying schematic drawings with further details.

FIG. 1 shows a schematic representation of a power electronic circuit including a gate driver circuit: and

FIG. 2 shows a schematic representation of various signal waveforms.

### DETAILED DESCRIPTION

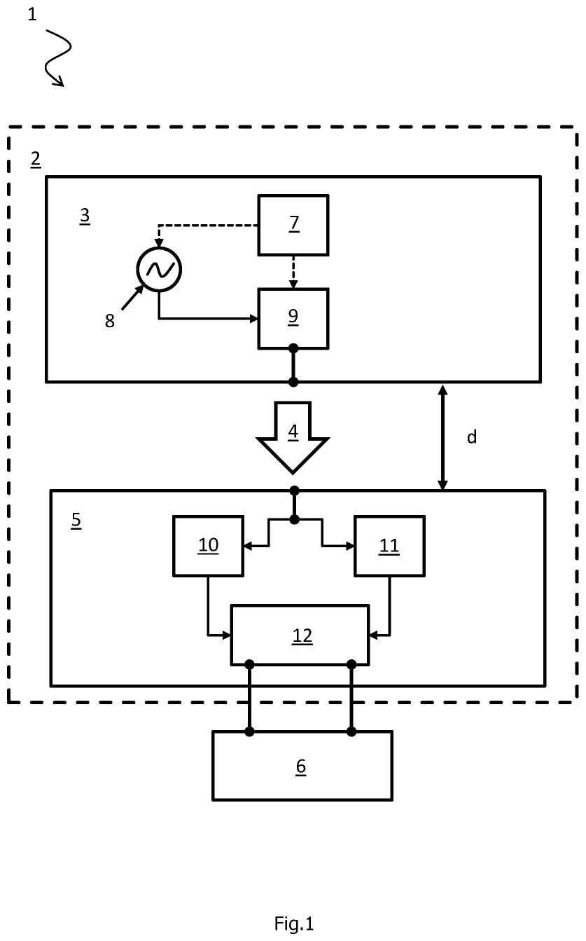

In FIG. 1, a power electronic circuit 1 is shown schematically. The power electronic circuit 1 has a gate driver circuit 2 with a low voltage part 3 and a high voltage part 5 spaced apart by a coupling section 4. The high voltage part is connected to the semiconductor circuit device 6 to be driven. All elements of the power electronic circuit 1 may be arranged on the same die, i.e., a semiconductor chip.

The coupling section 4 may include an insulation material or may be an air-air interface. The distance d between the low voltage part 3 and the high voltage part 5 is shown as an example. Here, the coupling section 4 may be located between corresponding coils, antennas or waveguides of the low voltage part 3 and the high voltage part 5. The coupling section 4 is used in particular for wireless unidirectional transmission of a digitally modulated signal between the low voltage part 3 and the high voltage part 5.

The digitally modulated signal is generated at the low voltage part 3. For this purpose, a switching signal generator 7 for providing a switching signal and a high frequency signal generator 8 for providing a high frequency signal are provided. Furthermore, a modulation signal generator 9 is provided to generate the digitally modulated signal by appropriately combining the high frequency signal with the switching signal to wirelessly transmit it to the high voltage part 5 via the coupling section 4. The modulation signal generator 9 may be an amplifier, for example.

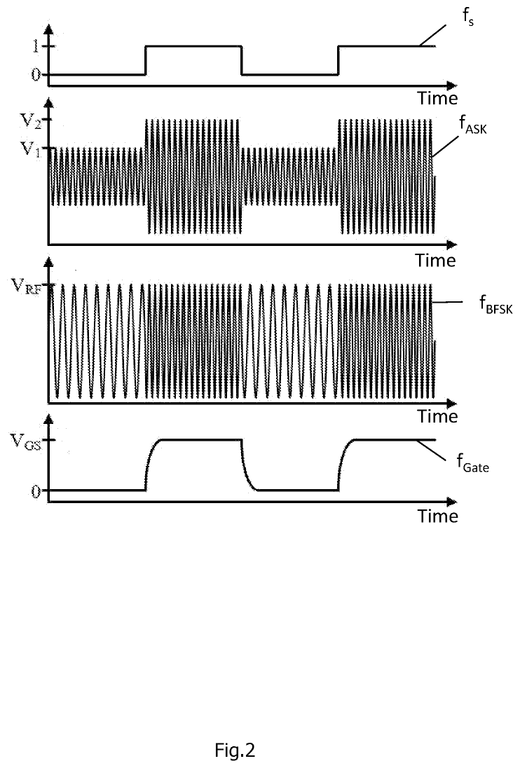

In the case of an ASK modulated signal (for this, see FIG. 2, ASK modulated signal fASK), the switching signal generator 7 can be connected to the supply voltage electrode (for example, drain in the case of a FET or collector in the case of a bipolar transistor) of the modulation signal generator 9. The switching signal generator 7 is thereby adapted to vary the supply voltage of the modulation signal generator 9 according to the switching signal fS (AN/Off corresponds to 1/0 in binary form) (see signal amplitudes V1 and V2 in FIG. 2). Here, the high frequency signal generator 8 is connected to the control electrode (for example, gate in the case of the FET or base in the case of a bipolar transistor) of the modulation signal generator 9. The high frequency signal generator 8, for example a local oscillator, is thereby adapted to provide a signal provided with a carrier frequency for modulating the switching signal provided by the switching signal generator 7. The ASK modulated signal fASK generated in this way can be forwarded by the supply voltage electrode of the modulation signal generator 9, for example via a capacitor connected between the supply voltage electrode of the modulation signal generator 9 and the coupling section 4, for transmission via the coupling section 4.

In the case of an FSK modulated signal (for this, see FIG. 2, BFSK modulated signal fBFSK), a predetermined supply voltage (see supply voltage VRF in FIG. 2) can be connected to the supply voltage electrode (for example, drain in the case of an FET or collector in the case of a bipolar transistor) of the modulation signal generator 9. The switching signal generator 7 together with the high frequency signal generator 8 is adapted to provide a frequency modulated high frequency signal corresponding to the switching signal (see FIG. 2, switching signal fS) and the carrier frequency. An output of this switching signal generator 7 and high frequency signal generator 8 is connected to the control electrode (e.g. gate in the case of the FET or base in the case of a bipolar transistor) of the modulation signal generator 9. Here, the frequency modulated high frequency signal is given to the control electrode of the modulation signal generator 9. The FSK modulated signal fBFSK generated in this way can be forwarded by the supply voltage electrode of the modulation signal generator 9, for example via a capacitor connected between the supply voltage electrode of the modulation signal generator 9 and the coupling section 4, for transmission via the coupling section 4.

The digitally modulated signal is received in both of the above cases at the high voltage part 5, after transmission by the low voltage part 3. For this purpose, a demodulation device 10, for demodulating the digitally modulated signal, and a rectifier 11, for rectifying the digitally modulated signal, are provided. Further, an output stage 12 is provided for generating the drive signal from the rectified signal as the power supply of the output stage and from the demodulated signal as the input signal of the output stage to drive the semiconductor circuit device 6.

In both cases described above as examples for ASK and FSK modulation, the result is a voltage fGate applied to the gate-source path (FET) or gate-emitter path (IGBT) of the semiconductor circuit device 6, which reflects the switching signal fS (see FIG. 2). VGS here represents the gate-source or gate-emitter voltage necessary to drive the semiconductor circuit device 6.

At this point, it should be noted that all of the above-described parts are claimed to be essential to the invention when considered alone and in any combination, especially the details shown in the figures. Modifications thereof are familiar to those skilled in the art.

### LIST OF REFERENCE SIGNS

1 power electronic circuit
2 gate driver circuit
3 low voltage part
4 coupling section
5 high voltage part
6 semiconductor circuit device
7 switching signal generator
8 high frequency signal generator
9 modulation signal generator
10 demodulation device
11 rectifier
12 output stage
d dimension
f_{S} switching signal
f_{BFSK} ASK modulated signal
f_{ASK} BFSK modulated signal
f_{Gate} gate-source voltage/gate-emitter voltage
V₁, V₂ signal amplitudes
V_{RF} supply voltage
V_{GS} gate-source voltage/gate-emitter voltage

1. An insulated gate driver circuit for driving a gate terminal of a semiconductor circuit device, the insulated gate driver circuit comprising:
a low voltage part; and
a high voltage part, wherein the low voltage part and the high voltage part are galvanically separated from each other by an insulated coupling section, and the low voltage part is adapted to transmit a signal to the high voltage part, wherein the high voltage part comprises an output stage adapted to drive the gate terminal of the semiconductor circuit device in dependence on a switching signal underlying the signal, wherein the insulated gate driver circuit is adapted to provide a power supply to the output stage and an input signal to the output stage based on the signal transmitted via the insulated coupling section.

2. The insulated gate driver circuit according to claim 1, wherein the signal to the high voltage part and the input signal are transmitted via the same coupling section.

3. The insulated gate driver circuit according to claim 1, wherein:
the high voltage part comprises a rectifier, which is adapted to generate a DC voltage by rectifying at least a part of the signal transmitted via the insulated coupling section and to provide it to the output stage;
the high voltage part comprises a demodulation device adapted to generate and provide to the output stage the input signal of the output stage reflecting the switching signal by demodulating at least a part of the signal transmitted via the insulated coupling section; and
the rectifier and the demodulation device are adapted to drive the output stage together based on one and the same signal.

4. The insulated gate driver circuit according to claim 1, wherein the coupling section has, on its output side, a signal divider which is adapted to divide the signal transmitted via the coupling section.

5. The insulated gate driver circuit according to claim 1, wherein the signal is a digitally modulated signal.

6. The insulated gate driver circuit according to claim 5, wherein the switching signal has two states which are mapped in a 2-ASK high-frequency signal by two different amplitudes or are mapped in a BFSK high-frequency signal by two different frequencies.

7. The insulated gate driver circuit according to claim 1, wherein:
the low voltage part comprises a switching signal generator adapted to generate the switching signal representing a desired switching state of the semiconductor circuit device;
the low voltage part comprises a high frequency signal generator adapted to generate a high frequency signal having a carrier frequency of the signal; and
the low voltage part comprises a modulation signal generator adapted to generate the signal based on a combination of the high frequency signal and the switching signal.

8. The insulated gate driver circuit according to claim 3, wherein the modulation signal generator is adapted for class E operation or class D operation and the rectifier is adapted for class E operation.

9. The insulated gate driver circuit according to claim 1, wherein the output stage is a linear amplifier.

10. A method of operating an insulated gate driver circuit according to claim 1, the method comprising:
providing a low voltage part and a high voltage part galvanically separated from each other by an insulated coupling section;
wirelessly transmitting a signal, from the low voltage part to the high voltage part via the insulated coupling section;
driving, by an output stage of the high voltage part, a gate terminal of the semiconductor circuit device in dependence on a switching signal underlying the signal; and
providing a power supply to the output stage and an input signal to the output stage based on the signal transmitted via the insulated coupling section.

11. The insulated gate driver circuit according to claim 1, wherein the signal is a multiple amplitude shift keying, M-ASK, high frequency signal or a frequency shift keying, FSK, high frequency signal.

12. The insulated gate driver circuit according to claim 1, wherein the signal is a 2-ASK high frequency signal or a binary FSK, BFSK, high frequency signal.

13. The insulated gate driver circuit according to claim 9, wherein the linear amplifier is a class AB linear amplifier.
